(19) United States
(12) Patent Application Publication
(10) Pub. No.: US 2003/0206399 A1
(43) Pub. Date: Nov. 6, 2003

(54) Monolithic electrical system and heat sink assembly

(76) Inventors: Kirby J. Chung, San Jose, CA (US); Michael Fashano, Canyon Lake, CA (US)

Correspondence Address: J. E. Kosinski, Loral Space & Communications, Ltd., Suite 303, 655 Deep Valley Drive, Rolling Hills Estates, CA, 90274, US

(21) Appl. No.: 10/137,963

(22) Filed: May 3, 2002

(51) Int. Cl. H05K 7/20

(52) U.S. Cl. 361/705; 361/704; 165/80.3; 174/252

(57) ABSTRACT

An electrical system and heat sink assembly is provided. The electrical system and heat sink assembly has a heat sink and more than one different electrical operational unit directly thermally coupled to the heat sink. At least one of the electrical operational units has a plurality of electrical components. A distribution panel is electrically connected to the electrical operational units. The distribution panel is directly electrically coupled to at least two of the electrical operational units. The distribution panel distributes power and control signals to the electrical operational units.

### BACKGROUND OF THE INVENTION

1. Field of the Invention

The present invention relates to an electrical system and, more particularly, to an electrical system and heat sink assembly.

2. Prior Art

U.S. Pat. No. 6,055,158 discloses an electronic component heat sink assembly having a printed circuit board with electronic components and a heat transfer member thermally connected to the electronic components. Electrical operational units having a plurality of electrical components are typically installed on a heat sink panel and interconnected with cables and multi wire harnesses. There is a related cost and complexity associated with the interconnected cables and multi wire harnesses that limits production capacity and creates reliability problems. Accordingly, there is a desire to provide the ability to integrate electrical operational units having a plurality of electrical components with a minimum of interconnected cables and multi wire harnesses.

### SUMMARY OF THE INVENTION

In accordance with one embodiment of the present invention, an electrical system and heat sink assembly is provided. The electrical system and heat sink assembly has a heat sink and more than one different electrical operational unit directly thermally coupled to the heat sink. At least one of the electrical operational units has a plurality of electrical components. A distribution panel is electrically connected to the electrical operational units. The distribution panel is directly electrically coupled to at least two of the electrical operational units. The distribution panel distributes power and control signals to the electrical operational units.

In accordance with a second embodiment of the present invention, an electrical system and heat sink assembly is provided. More than one different electrical operational unit is thermally coupled directly to a heat sink. At least one of the electrical operational units has a plurality of electrical components. A distribution panel is electrically connected to the electrical operational units. The distribution panel is directly structurally coupled to the heat sink. The distribution panel is adapted to distribute power and control signals to all the electrical operational units.

In accordance with one method of the present invention, a method of integrating electrical operational units is provided. More than one different electrical operational units is thermally coupling directly to a heat sink. At least one of the electrical operational units has a plurality of electrical components. Power and control signals are distributed to the electrical operational units with a distribution panel fixedly attached to the heat sink.

### BRIEF DESCRIPTION OF THE DRAWINGS

The foregoing aspects and other features of the present invention are explained in the following description, taken in connection with the accompanying drawings, wherein:

FIG. 1 is a perspective view of an electrical system and heat sink assembly incorporating features of the present invention;

FIG. 2 is a perspective view of an alternate embodiment electrical system and heat sink assembly incorporating features of the present invention;

FIG. 3 is a perspective view of an alternate embodiment electrical system and heat sink assembly incorporating features of the present invention;

FIG. 4 is a schematic cross section view of an electrical operational unit of FIG. 3;

FIG. 5 is a schematic cross section view of an alternate embodiment of an electrical operational unit of FIG. 3;

FIG. 6 is a schematic cross section view of an electrical operational unit of FIGS. 1, 2 or 3 showing an alternative electrical interface; and

FIG. 7 is a flow diagram of a method incorporating features of the present invention.

### DETAILED DESCRIPTION OF THE PREFERRED EMBODIMENT

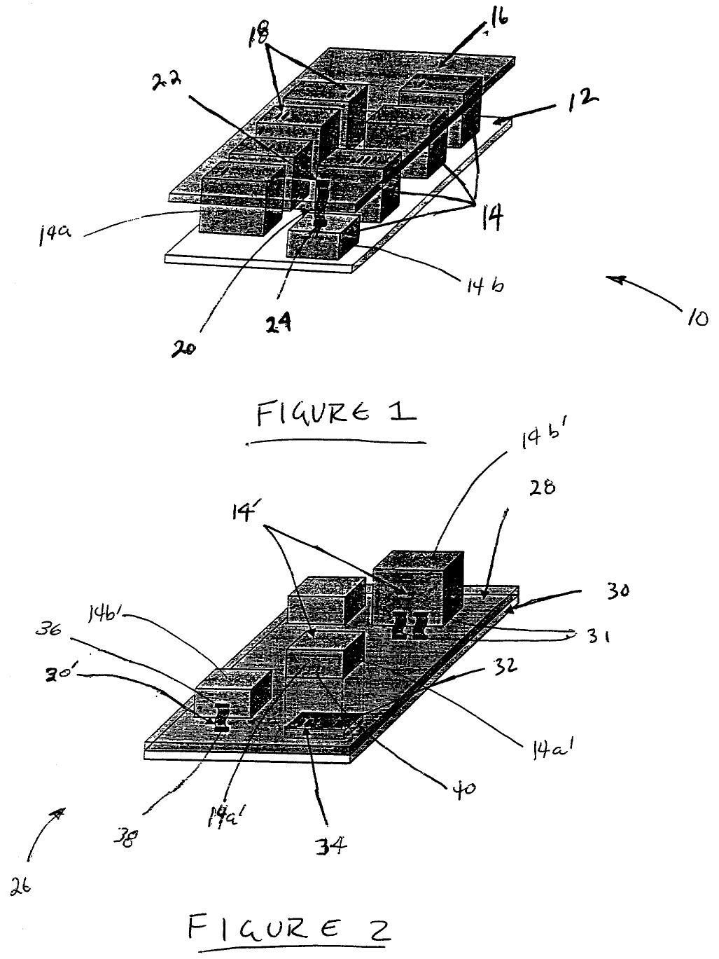

Referring to FIG. 1, there is shown a perspective view of a n electrical system and heat sink assembly 10 incorporating features of the present invention. Although the present invention will be described with reference to the embodiments shown in the drawings, it should be understood that the present invention can be embodied in many alternate forms of embodiments. In addition, any suitable size, shape or type of elements or materials could be used.

Electrical system and heat sink assembly 10 generally comprises a heat sink 12, different electrical operational units 14, and a distribution panel 16. However, in alternate embodiments the assembly 10 could comprise additional components. The assembly 10 is preferably adapted to be used as a sub-component in another device, such as a spacecraft or satellite, for example. However, the assembly 10 could be used in any suitable type of device. Preferably, the assembly 10 can be removably connected to the larger receiving device, such as in a modular removable fashion so it can be connected and removed in a one piece modular manner. However, any suitable type of connection could be provided, including multiple separate removable and/or fixed non-removable connections to the receiving device. Heat sink 12 generally comprises a thermally conductive material, such as aluminum, which readily conducts heat. However, any suitable type of material(s) could be used.

Heat sink 12 is provided to remove heat from the different electrical operational units 14. Heat sink 12 may include a plurality of cooling fins in order to increase the surface area of heat sink 12 and, thus, maximize the transfer of heat from heat sink 12 device into the surrounding air or environment. In this manner, heat sink 12 draws heat away from operational units 14 and transfers the heat into the surrounding air or environment. Heat sink 12 may incorporate a fan to assist cooling and increase the cooling capacity of heat sink 12. The fan causes air to move over and around the surface of heat sink 12, thus cooling the surface by enhancing the transfer of heat from the surface into the ambient air or surrounding environment. Heat sink 12 is usually placed in thermal contact with operational units 14. This thermal contact may be by direct contact or alternately with the assistance of a thermally conductive compound employed directly between heat sink 12 and operational units 14. Due to this thermal contact, heat generated by the operational units 14 is conducted into heat sink 12 and away from the operational units 14. Heat sink 12 may alternately be comprised of an active conduction cooling system, such as heat pipes or a re-circulating chiller. Heat sink 12 may alternately be comprised of a radiative cooling system. In alternate embodiments, any suitable type of heat sink could be provided.

In the embodiment shown the assembly 10 has a plurality of the operational units 14. The operational units 14 could include any type of electrical device requiring electrical connections to an external system and from which heat is to be removed. The operational units 14 could include devices such as an amplifier, a power supply, a power converter, a power transformer, a logic controller, a central processing unit, a power contactor, input and output modules, or any other suitable type of electrical subsystem. At least some of the operational units 14 include a plurality of internal electrical components. Assembled together with a common structure and providing a function or functions as part of the whole system. Although the assembly 10 is shown with eight operational units 14, the assembly could have more or less than eight operational units. In the embodiment shown, the assembly 10 has two different size height operational units 14a, 14b. However, in alternate embodiments an assembly could be provided having operational units with more or less than two different size heights.

Each operational unit 14 requires electrical power and/or has an input and/or output (I/O) device for transmission of signals or other information. Connections are provided to allow power and signals to be transferred between the operational units 14 and the distribution panel 16. Although the connections will be described in detail below, it should be understood that any suitable type of operational connection(s) could be provided between the operational units 14 and another member.

In the embodiment shown, the operational units 14 are shown as having at least two different types of connectors 18, 24. In alternate embodiments more or less that two types of connectors could be provided. In addition, at least one of the operational units 14 might have more than one connector and might have more than one type of connector. The connectors are provided for the transmission of power and/or signals with the operational units 14. In the embodiment shown, the first type of connector 18 is provided on the higher height operational units 14a and the second type of connectors 24 are provided on the lower height operational units 14b. The connectors could include electrical connectors and/or optical connectors.

In this embodiment the operational units 14 are fixedly connected to the heat sink 12. The different electrical operational units 14 may generate small amounts or significant amounts of heat. If this heat is not continuously removed, the electrical operational units 14 may overheat, resulting in damage to the device and/or a reduction in operating performance. As noted above, the heat sink 12 is provided to remove the heat from the operational units 14. In the embodiment shown, in order to accomplish this heat removal function, the operational units are directly attached or substantially directly attached to the heat sink 12. Any suitable means could be used to attach the operational units 14 to the heat sink 12. For example, fasteners such as screws, clips, rivets or any other suitable means could be used to attach the operational units 14 to the heat sink 12.

The distribution panel 16 generally comprises a layered printed circuit board with a plurality of layers for distributing power and/or signals between one or more operational units 14 and with another device when the assembly 10 is adapted to be used as a sub-component in the other device. Power and/or signal are distributed within distribution panel 16 with electrically conductive elements such as printed or etched conductors. Power and/or signals may alternately be distributed within distribution panel 16 alone or in combination with optical conductors. The conductors may reside in one of a plurality of layers within distribution panel 16. Alternately, the conductors may reside on or within distribution panel 16 in any alternate suitable manner. Distribution panel 16 may further incorporate jumper wires or optical conductors attached to distribution panel 16 in order to distribute power and/or control signals. Distribution panel 16 may further incorporate an interface such as an electrical and/or optical contactor, connector or harness in order to allow the assembly 10 to be removably connected to a larger receiving device, such as in a modular removable fashion so that assembly 10 can be connected and removed in a one piece modular manner.

Distribution panel 16 is electrically and/or optically connected to the electrical operational units 14. Distribution panel 16 is directly electrically coupled to at least two of the electrical operational units 14 via connectors 18. Distribution panel 16 distributes power and control signals to the electrical operational units 14 via connectors 18 and 22. Connectors 18 may comprise pin and plug optical and/or electrical connectors. Connectors 18 may alternately be any suitable type of connector for transmitting electrical signals or power or optical signals.

Each electrical operating unit 14 may alternately interface with distribution panel 16 with one or a plurality of harnesses 20 via connectors 24 and 22. Connectors 18, 24 and 22 may be plug type connectors, pressure contacts, interfacing electrically conductive surfaces, optical connectors or any other suitable type of connector for coupling electrical power and/or optical or electrical inputs or outputs for logic or otherwise between electrical operating units 14 and distribution panel 16. Harness 20 may be a wire harness incorporating a plurality of wires to transmit power or electrical signals between electrical operating units 14 and distribution panel 16. Harness 20 may alternately incorporate a plurality of optical fiber bundles alone or in combination with a plurality of wires. In an alternate embodiment, harness 20 may not be provided and replaced with connectors on standoffs to accommodate the space between operating unit 14b and distribution panel 16.

Distribution panel 16 is fixedly attached to heat sink 12 via electrical operating units 14. In this manner, the combination of electrical operating units 14 and connectors 18 provide the structural support for distribution panel 16. Distribution panel 16 may alternately be fixedly attached to heat sink 12 via a combination of electrical operating units 14 and/or standoffs, fasteners or otherwise, where the standoffs, fasteners or otherwise may or may not be rigid.

Referring now to FIG. 2, there is shown a perspective view of an alternate embodiment electrical system and heat sink assembly 26 incorporating features of the present invention. Electrical system and heat sink assembly 26 generally comprises a heat sink 30, different electrical operational units 14′, and a distribution panel 28. However, in alternate embodiments the assembly 26 could comprise additional components. The assembly 26 is preferably adapted to be used as a sub-component in another device with features allowing integration with the other device similar to those described for the assembly 10 of FIG. 1.

Heat sink 30 generally comprises a thermally conductive material, such as aluminum, which readily conducts heat. However, any suitable type of material(s) could be used. Heat sink 30 is provided to remove heat from the different electrical operational units 14′ and may incorporate the features and benefits of heat sink 12 of FIG. 1. Heat is directly transferred from the operational units 14′ to the heat sink 30 through distribution panel 28. In an alternate embodiment, heat may be directly transferred from the operational units 14′ to the heat sink 30 by protrusions 31 of heat sink 30 and/or operational units 14′ that protrude completely or in part through distribution panel 28. Heat is transferred from operational units 14′ to the heat sink 30 by thermal contact between them and/or with distribution panel 28. This contact may be direct or alternately with the assistance of a thermally conductive compound employed at the thermal interface.

In the embodiment shown the assembly 26 has a plurality of the operational units 14′. The operational units 14′ may incorporate features of operational units 14 of FIG. 1. Although the assembly 26 is shown with four operational units 14′, the assembly could have more or less than four operational units 14 of varying size and shape. Connections are provided to allow power and signals to be transferred between the operational units 14′ and the distribution panel 28. Although the connections will be described in detail below, it should be understood that any suitable type of operational connection(s) could be provided between the operational units 14′ and another member.

In the embodiment shown, the operational units 14′ are shown as having at least two different types of connectors 40, 36. In alternate embodiments more or less that two types of connectors could be provided. In addition, at least one of the operational units 14′ might have more than one connector and might have more than one type of connector. In the embodiment shown, the first type of connector 40 is provided on the side of operational unit 14a′ that interfaces with distribution panel 28. A second type of connectors 36 is provided on a side of operational units 14b′. Although the connectors 40 and 36 are placed as shown on operational units 14a′ and 14b′, any suitable placement could be used. The connectors could include electrical connectors and/or optical connectors.

In this embodiment the operational units 14′ are fixedly connected to the disribution panel 28. Any suitable means could be used to attach the operational units 14′ to the distribution panel 28. For example, fasteners such as screws, clips, rivets or any other suitable means could be used to attach the operational units 14′ to distribution panel 28. In an alternate embodiment, no fasteners would be used. Instead, connectors such as connectors 34 and 40 would be used to attach the operational units 14′ to distribution panel 28. In an alternate embodiment, operational units 14′ may be fixedly connected to the heat sink 30 either directly with a fastening device or through distribution panel 28 with a fastening device.

The distribution panel 28 generally comprises a layered printed circuit board with a plurality of layers for distributing power and/or signals between one or more operational units 14′ and with another device when the assembly 26 is adapted to be used as a sub-component in the other device. Power and/or signal are distributed within distribution panel 28 and/or to a larger receiving device in a similar manner as distribution panel 16 shown in FIG. 1.

Distribution panel 28 comprises a thermal interface 32. Thermal interface 32 allows heat to be directly transferred between operating unit 14a′ and heat sink 30. Thermal interface 32 generally comprises a thermally conductive material. The thermally conductive material may be embedded in or be part of distribution panel 28. Thermal interface 32 may comprise a metallized surface on opposing sides of distribution panel 28 and filled via holes within distribution panel 28. In an alternate embodiment, the surfaces on opposing sides may comprise any thermally conductive material or may alternately be the surface of distribution panel 28. The opposing metallized surfaces thermally interface with operating unit 14a′ and heat sink 30. There may be one or a plurality of filled via holes between the metallized surfaces to enable thermal transfer between operating unit 14a′ and heat sink 30. The holes are filled with a thermally conductive material, such as aluminum, which readily conducts heat. However, any suitable type of material(s) could be used such as a thermally conductive compound or otherwise. In an alternate embodiment, no holes are provided and the distribution panel 28 itself is utilized to enable thermal transfer between operating unit 14a′ and heat sink 30. One or more of the operating units 14′ may transfer heat between operating units 14′ and heat sink 30 in a similar manner as herein described.

Distribution panel 28 is electrically and/or optically connected to the electrical operational units 14′. Distribution panel 28 is directly electrically coupled to the electrical operational unit 14a′ via connectors 34 and 40. Connectors 34 and 40 may comprise pin and plug optical and/or electrical connectors. Connectors 34 and 40 may alternately be any suitable type of connector for transmitting electrical signals or power or optical signals. Connectors 34 and 40 are shown directly between operating unit 14a′ and distribution panel 28 but may alternately be placed otherwise as offset from the thermal interface 32.

Each electrical operating unit 14′ may alternately interface with distribution panel 28 with one or a plurality of harnesses 20′ via connectors 38 and 36. Connectors 38 and 36 may be plug type connectors, pressure contacts, interfacing electrically conductive surfaces, optical connectors or any other suitable type of connector for coupling electrical power and/or optical or electrical inputs or outputs for logic or otherwise between electrical operating units 14′ and distribution panel 28. Harness 20′ may be a wire harness incorporating a plurality of wires to transmit power or electrical signals and may incorporate features of harness 20 shown in FIG. 1. In an alternate embodiment, harness 20′ may not be provided and replaced with connectors on standoffs and/or offset from the sides of operating unit 14b′.

Distribution panel 28 is fixedly attached to heat sink 30 with standoffs, fasteners or otherwise, where the standoffs, fasteners or otherwise may or may not be rigid.

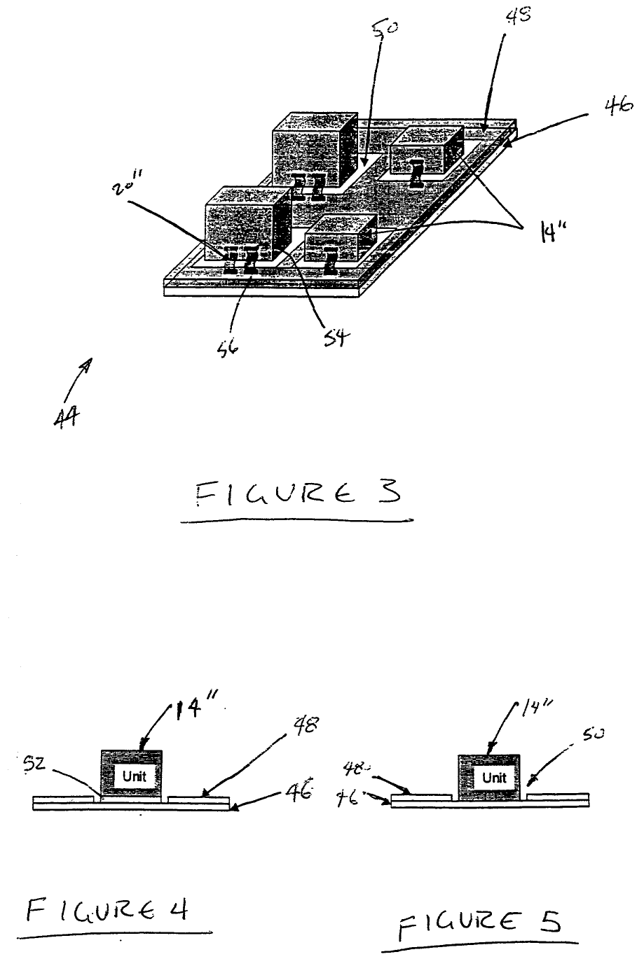

Referring now to FIG. 3, there is shown a perspective view of an alternate embodiment electrical system and heat sink assembly 44 incorporating features of the present invention. Electrical system and heat sink assembly 44 generally comprises a heat sink 46, different electrical operational units 14″, and a distribution panel 48. However, in alternate embodiments the assembly 44 could comprise additional components. The assembly 44 is preferably adapted to be used as a sub-component in another device with features allowing integration with the other device similar to those described for the assembly 10 of FIG. 1 or the assembly 26 of FIG. 2.

Heat sink 46 generally comprises a thermally conductive material, such as aluminum, which readily conducts heat. However, any suitable type of material(s) could be used. Heat sink 46 is provided to remove heat from the different electrical operational units 14″ and may incorporate the features and benefits of heat sink 12 of FIG. 1 or heat sink 30 of FIG. 2. Heat is directly transferred from the operational units 14″ to the heat sink 46 due to direct thermal contact with operational units 14″. This contact arises from a cutout 50 in distribution panel 48, allowing operational units 14″ to physically contact heat sink 46 or transfer heat with a thin layer of thermally conductive compound or otherwise.

Referring also to FIG. 4, there is shown a schematic cross section view of an electrical operational unit 14″ of FIG. 3. Electrical operational unit 14″ is shown mounted on heat sink 46 with pedestal 52. Heat sink 46 is placed in direct thermal contact with operational units 14″ via pedestal 52. Pedestal 52 may be molded or machined integral with heat sink 46. Pedestal 52 may alternately be a separate material suitable to transfer heat from operational unit 14″ to heat sink 46. A thin layer of thermally conductive compound may be employed between pedestal 52 and heat sink 46 or between pedestal 52 and operational unit 14″. Pedestal 52 may be the same thickness as distribution panel 48 but may alternately be different thickness.

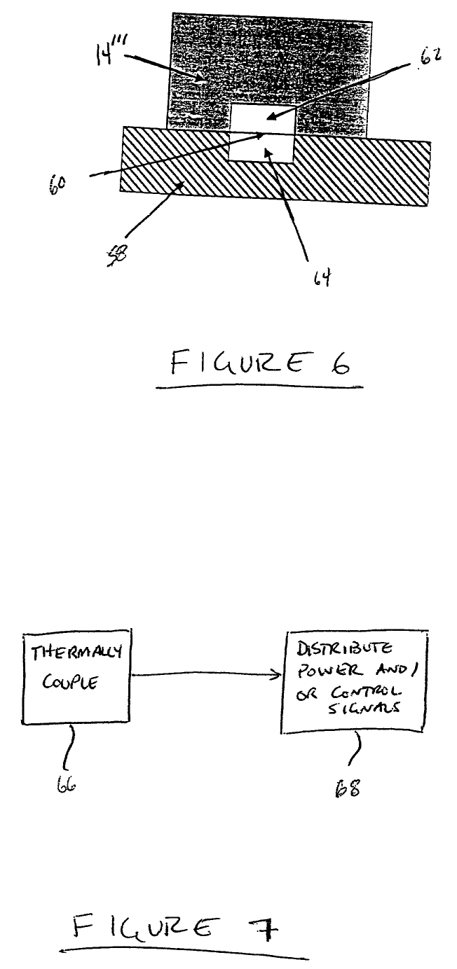

Referring also to FIG. 5, there is shown a schematic cross section view of an alternate embodiment electrical operational unit 14″ of FIG. 3. Electrical operational unit 14″ is shown mounted on heat sink 46. Heat sink 46 is placed in direct thermal contact with operational units 14″ as herein described. Although operational unit 14″ is shown mounted to heat sink in opening 50 coplanar with distribution panel 48, operational unit 14″ may alternately be mounted in a recess or on a protrusion on heat sink 46.

In the embodiment shown the assembly 44 has a plurality of the operational units 14″. The operational units 14″ may incorporate features of operational units 14 of FIG. 1 or 14′ of FIG. 2. Although the assembly 44 is shown with four operational units 14″, the assembly could have more or less than four operational units 14″ of varying size and shape. Connections are provided to allow power and signals to be transferred between the operational units 14″ and the distribution panel 46. Although the connections will be described in detail below, it should be understood that any suitable type of operational connection(s) could be provided between the operational units 14″ and another member.

In the embodiment shown, the operational units 14″ are shown as having one type of connector 54. In alternate embodiments more or less that one type of connector could be provided. In addition, at least one of the operational units 14″ might have more than one connector and might have more than one type of connector. In the embodiment shown, the connector 54 is provided on a side of operational units 14″. Although the connector 54 is placed as shown, any suitable placement could be used. The connector could include electrical connectors and/or optical connectors.

In this embodiment the operational units 14″ are fixedly connected to the heat sink 46. Any suitable means could be used to attach the operational units 14″ to the heat sink 46. For example, fasteners such as screws, clips, rivets or any other suitable means could be used to attach the operational units 14″ to heat sink 46. In an alternate embodiment, no fasteners would be used. In an alternate embodiment, operational units 14″ may be fixedly connected to the distribution panel 48 either with a fastening device and/or a connector.

The distribution panel 48 generally comprises a layered printed circuit board with a plurality of layers for distributing power and/or signals between one or more operational units 14″ and with another device when the assembly 44 is adapted to be used as a sub-component in the other device. Power and/or signal are distributed within distribution panel 48 and/or to a larger receiving device in a similar manner as distribution panel 16 shown in FIG. 1 or distribution panel 28 shown in FIG. 2. Distribution panel 48 is fixedly attached to heat sink 46 with standoffs, fasteners or otherwise, where the standoffs, fasteners or otherwise may or may not be rigid.

Distribution panel 48 is electrically and/or optically connected to the electrical operational units 14″. Each electrical operating unit 14″ may connect with distribution panel 48 with one or a plurality of harnesses 20″ via connectors 54 and 56. Connectors 54 and 56 may be plug type connectors, pressure contacts, interfacing electrically conductive surfaces, optical connectors or any other suitable type of connector for coupling electrical power and/or optical or electrical inputs or outputs for logic or otherwise between electrical operating units 14″ and distribution panel 48. Harness 20″ may be a wire harness incorporating a plurality of wires to transmit power or electrical signals and may incorporate features of harness 20 shown in FIG. 1. In an alternate embodiment, harness 20″ may not be provided and replaced with connectors on standoffs and/or offset from the sides of operating unit 14b′. In a further alternate embodiment, harness 20″ may not be provided and replaced with connectors described as with the embodiment shown in FIG. 1 or FIG. 2.

Referring now to FIG. 6, there is shown a schematic cross section view of an electrical operational unit 14′″ of FIGS. 1, 2 or 3 showing an alternative electrical interface between electrical operating unit 14′″ and distribution panel 58. Distribution panel 58 is electrically and/or optically connected to the electrical operational units 14′″ at interface 60. Interface 60 may incorporate a wireless signal interface such as electrically or inductively coupled or optically coupled interface. Although interface 60 is shown directly between operational unit 14′″ and distribution panel 58, interface 60 may alternately be located at any suitable position, as on the side of operational unit 14′″. Although interface 60 is shown as contact between operational unit 14′″ and distribution panel 58, interface 60 may alternately have clearance between operational unit 14′″ and distribution panel 58 as in the case of a wireless or optical interface.

Each of electrical operational units 14′″ comprises a set or arrangement of electrical components connected as to form a functional electrical subsystem and incorporates features similar to those electrical operational units of FIGS. 1, 2 or 3. Electrical operational units 14′″ are electrically and/or optically connected to distribution panel 58 at interface 60 via interconnect 62. Interconnect 62 may be embedded in electrical operational units 14′″. Interconnect 62 may incorporate a wireless signal interface such as electrically or inductively coupled or optically coupled interface. Interconnect 62 may further incorporate plug type connectors, pressure contacts, interfacing electrically conductive surfaces, optical connectors or other type of connector suitable for coupling electrical power and/or optical or electrical inputs or outputs for logic or otherwise between electrical operating units 14′″ and distribution panel 58. Interconnect 62 may incorporate a single electrical and/or optical interface or alternately a plurality of electrical and/or optical interfaces.

Distribution panel 58 is electrically and/or optically connected to the electrical operational units 14′″ at interface 60. Distribution panel 48 distributes power and control signals to the electrical operational units 14′″ via interface 60. Distribution panel 58 incorporates features similar to those distribution panels of FIGS. 1, 2 or 3. Electrical operational units 14′″ are electrically and/or optically connected to distribution panel 58 at interface 60 via interconnect 64. Interconnect 64 may be embedded in distribution panel 68 and may incorporate features complimentary to interconnect 62.

Referring now to FIG. 7, there is shown a flow diagram of a method incorporating features of the present invention. The method of integrating electrical operational units comprises a step 66 of thermally coupling more than one different electrical operational units directly to a heat sink. Thermally coupling may occur by direct contact or directly as with a thermally conductive compound or as with a thermally conductive material between the electrical operational units and the heat sink or otherwise. At least one of the electrical operational units comprises a plurality of electrical components. The method further comprises a step 68 of distributing power and control signals to the electrical operational units with a distribution panel fixedly attached to the heat sink. Power and control signals may be distributed directly as with wires or optical connections or as by a wireless interface such as an optical interface or inductivly coupled electrical interface.

It should be understood that the foregoing description is only illustrative of the invention. Various alternatives and modifications can be devised by those skilled in the art without departing from the invention. Such alternatives and modifications include combining features of the various embodiments shown or adding features to those embodiments. Accordingly, the present invention is intended to embrace all such alternatives, modifications and variances which fall within the scope of the appended claims.

What is claimed is:

1. A electrical system and heat sink assembly comprising:
a heat sink;
more than one different electrical operational unit directly thermally coupled to the heat sink, at least one of the electrical operational units comprising a plurality of electrical components; and
a distribution panel electrically connected to the electrical operational units, the distribution panel being directly electrically coupled to at least two electrical operational units;
wherein the distribution panel is adapted to distribute power and control signals to the electrical operational units.

2. The electrical system and heat sink assembly of claim 1, wherein an adapter harness electrically couples at least one operational unit to the distribution panel.

3. The electrical system and heat sink assembly of claim 1, wherein the distribution panel is directly structurally coupled to the heat sink.

4. The electrical system and heat sink assembly of claim 1, wherein the distribution panel is directly electrically coupled to at least two electrical operational units with a plug interface.

5. The electrical system and heat sink assembly of claim 1, wherein the distribution panel is directly electrically coupled to at least two electrical operational units with a wireless signal interface connection.

6. The electrical system and heat sink assembly of claim 1, wherein the more than one different electrical operational unit is directly thermally coupled to the heat sink with a heat transfer compound.

7. The electrical system and heat sink assembly of claim 6, wherein the heat transfer compound is embedded in the distribution panel.

8. The electrical system and heat sink assembly of claim 1, wherein the more than one different electrical operational unit is directly thermally coupled to the heat sink with the distribution panel.

9. A electrical system and heat sink assembly comprising:
more than one different electrical operational unit thermally coupled directly to a heat sink, at least one of the electrical operational units comprising a plurality of electrical components; and
a distribution panel electrically connected to the electrical operational units, the distribution panel being directly structurally coupled to the heat sink;
wherein the distribution panel is adapted to distribute power and control signals to all the electrical operational units.

10. The electrical system and heat sink assembly of claim 9, wherein an adapter harness electrically couples at least one operational unit to the distribution panel.

11. The electrical system and heat sink assembly of claim 9, wherein the heat sink is coupled to a first side of the distribution panel and, wherein the electrical operational units are coupled to a second side of the distribution panel.

12. The electrical system and heat sink assembly of claim 9, wherein the distribution panel is directly electrically coupled to at least one electrical operational unit with a plug interface.

13. The electrical system and heat sink assembly of claim 9, wherein the distribution panel is directly electrically coupled to at least one electrical operational unit with a wireless signal interface connection.

14. The electrical system and heat sink assembly of claim 9, wherein the more than one different electrical operational unit is directly thermally coupled to the heat sink with a heat transfer compound.

15. The electrical system and heat sink assembly of claim 14, wherein the heat transfer compound is embedded in the distribution panel.

16. The electrical system and heat sink assembly of claim 9, wherein the more than one different electrical operational unit is directly thermally coupled to the heat sink with the distribution panel.

17. A method of integrating electrical operational units comprising the steps of:
thermally coupling more than one different electrical operational units directly to a heat sink, at least one of the electrical operational units comprising a plurality of electrical components; and
distributing power and control signals to the electrical operational units with a distribution panel fixedly attached to the heat sink.

18. The method of integrating electrical operational units of claim 17 further comprising the step of directly electrically coupling at least one of the electrical operational units to the distribution panel.

19. The method of integrating electrical operational units of claim 17 further comprising the step of electrically coupling at least one of the electrical operational units to the distribution panel with a adapter harness.

20. The method of integrating electrical operational units of claim 17 further comprising the step of electrically coupling at least one of the electrical operational units to the distribution panel with a wireless connection.
